(19) United States
(12) Patent Application Publication
(10) Pub. No.: US 2016/0037655 A1
(43) Pub. Date: Feb. 4, 2016

(54) DISPLAY DEVICE

(71) Applicant: SAMSUNG DISPLAY CO., LTD., Yongin-si (KR)

(72) Inventors: Dong Sung Im, Asan-si (KR); Hyun Su Park, Hwaseong-si (KR); Gyu Su Lee, Asan-si (KR)

(21) Appl. No.: 14/620,153

(22) Filed: Feb. 11, 2015

(30) Foreign Application Priority Data
Jul. 30, 2014 (KR) 10-2014-0097351

(51) Int. Cl. H05K 5/00; H05K 5/02; G02B 5/30; H05K 7/14

(52) U.S. Cl. CPC H05K 5/0017; H05K 7/1427; H05K 5/0217; G02B 5/3033

(57) ABSTRACT

A display device includes a display panel; an upper frame configured to cover an edge portion of an upper surface and side surfaces of the display panel; a pad between the display panel and the upper frame; and a film member between the pad and the display panel.

### CROSS-REFERENCE TO RELATED APPLICATION

This application claims priority to and the benefit of Korean Patent Application No. 10-2014-0097351, filed on Jul. 30, 2014 with the Korean Intellectual Property Office, the disclosure of which is incorporated herein in its entirety by reference.

### BACKGROUND

1. Field

The present disclosure relates to a display device including a narrow bezel.

2. Description of the Related Art

Display elements can be categorized into a liquid crystal display (LCD), an organic light emitting display (OLED), a plasma display panel (PDP), an electrophoretic display (EPD), or the like.

A display device includes a display panel including a plurality of pixels for displaying images, a middle and a lower frame for supporting and accommodating the display panel, an upper frame for covering an edge portion of an upper surface and side surfaces of the display panel, and a pad disposed between the display panel and the upper frame.

The pad may be disposed between the upper frame and the display panel. The pad may serve or perform a variety of functions including preventing damage to the display panel caused by the upper frame, releasing static-electric charges to outside the display panel, and preventing light leakage between the upper frame and the display panel. The pad may be fixed to the upper frame by using an adhesive member, such as double-sided tape.

Meanwhile, in recent years, the display devices have been designed to reduce or minimize an area where the upper frame and the display panel overlap in order to reduce or minimize a non-display area. Therefore, a contacting area between the upper frame and the pad is reduced, thereby weakening adhesion between the upper frame and the pad. As a result, the display panel may move due to, for example, vibration, such that the pad may be detached from the upper frame.

It is to be understood that this background of the technology section is intended to provide useful background for understanding the technology disclosed herein, and as such, this background section may include ideas, concepts, or recognitions that were not part of what was known or appreciated by those skilled in the pertinent art prior to a corresponding effective filing date of the subject matter disclosed herein.

### SUMMARY

An aspect of the present disclosure is directed to a display device including a narrow bezel designed to prevent detachment of a pad disposed between an upper frame and a display panel.

According to an embodiment of the present invention, a display device includes: a display panel; an upper frame configured to cover an edge portion of an upper surface and side surfaces of the display panel; a pad between the display panel and the upper frame; and a film member between the pad and the display panel.

A coefficient of static friction between the pad and the film member may be greater than a coefficient of static friction between the film member and the display panel.

The upper frame may include a bezel portion (e.g., a bezel unit) covering the edge portion of the upper surface of the display panel and a sidewall portion bent (e.g., bent downwards) from the bezel portion and covering the side surfaces of the display panel.

The pad may be between the bezel portion of the upper frame and the display panel.

The film member may be bent toward the sidewall portion of the upper frame and may be between the sidewall portion of the upper frame and the side surfaces of the display panel.

The film member may be attached to the sidewall portion of the upper frame.

The display panel may include a substrate and a polarizer on the substrate, and the film member may be between the pad and the polarizer.

A coefficient of static friction between the pad and the film member may be greater than a coefficient of static friction between the film member and the polarizer.

The film member may have a quadrangular shape extending along the upper frame.

The film member may have a strap shape extending along the upper frame.

The film member may include two or more separate pieces.

The two or more pieces of the film member may be at opposite sides of the upper frame.

The film member may include a polytetrafluoroethylene-based film, a flame-retarding polyvinyl chloride film, a flame-retarding polyester film, a flame-retarding polyether film, a polyethyleneimine film, a silicon film, a silicon rubber film, a fluorine resin film, an insulating film, a teflon film, a polyvinyl chloride-based protective film, a polyethylene-based film, and/or a polyolefin-based film.

The film member may be opaque.

A thickness of the film member may be smaller than a gap between the sidewall portion of the upper frame and the display panel.

According to embodiments of the present invention, a display device includes a film member between a pad and a display panel, thereby preventing (or protecting from) detachment of the pad from the upper frame.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure will be more clearly understood from the following detailed description taken in conjunction with the accompanying drawings, in which:

FIG. 1 is an exploded perspective view illustrating a display device according to an embodiment of the present invention;

FIG. 2 is an inner perspective view taken along the line I-II of FIG. 1;

FIG. 3 is a cross-sectional view taken along the line III-IV of FIG. 1; and

FIGS. 4 to 6 are rear views showing an upper frame to illustrate an arrangement of a film member according to embodiments of the present invention.

### DETAILED DESCRIPTION

Hereinafter, embodiments of the present disclosure will be described in more detail with reference to the accompanying drawings.

Although the present invention can be modified in various manners and have several embodiments, specific embodiments are illustrated in the accompanying drawings and will be mainly described in the specification. However, the scope of the embodiments of the present invention is not limited to the specific embodiments and should be construed as including all changes, equivalents, and substitutions included in the spirit and scope of the present invention.

Throughout the specification, when an element is referred to as being “connected” to another element, the element may be “physically connected” to the other element or “electrically connected” to the other element. It will be understood that when an element or layer is referred to as being “on”, “connected to”, or “coupled to” another element or layer, it may be directly on, connected, or coupled to the other element or layer or one or more intervening elements or layers may also be present. When an element is referred to as being “directly on”, “directly connected to”, or “directly coupled to” another element or layer, there are no intervening elements or layers present. It will be further understood that the terms “comprises,” “comprising,” “includes” and/or “including,” when used in this specification, specify the presence of stated features, integers, steps, operations, elements, and/or components but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are used to distinguish one element from another element. Thus, a “first element” discussed below could be termed a “second element” or a “third element,” and a “second element” and a “third element” can be termed likewise without departing from the teachings herein. As used herein, the term “and/or” includes any and all combinations of one or more of the associated listed items. Further, the use of “may” when describing embodiments of the present invention relates to “one or more embodiments of the present invention”. The terminology used herein is for the purpose of describing particular example embodiments only and is not intended to be limiting of example embodiments. As used herein, the singular forms “a”, “an”, and “the” are intended to include the plural forms as well, unless the context clearly indicates otherwise.

Spatially relative terms, such as “beneath,” “below,” “lower,” “downward,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise orientated (rotated 90 degrees or at other orientations) and the spatially relative descriptors used herein should be interpreted accordingly.

Expression, such as “at least one of,” when preceding a list of elements, modify the entire list of elements and do not modify the individual elements of the list. Further, the use of “may” when describing embodiments of the inventive concept refers to “one or more embodiments of the inventive concept.” Also, the term “exemplary” is intended to refer to an example or illustration.

As used herein, the terms “use,” “using,” and “used” may be considered synonymous with the terms “utilize,” “utilizing,” and “utilized,” respectively.

Some of the parts which are not necessary to the description of embodiments of the present invention may be omitted in the description of the embodiments of the present invention herein, and like reference numerals refer to like elements throughout the specification.

Hereinafter, it is assumed that an LCD is used as a display device according to an embodiment of the present invention. However, it is obvious that the present invention can be applied to an OLED display or a PDP in addition to the LCD.

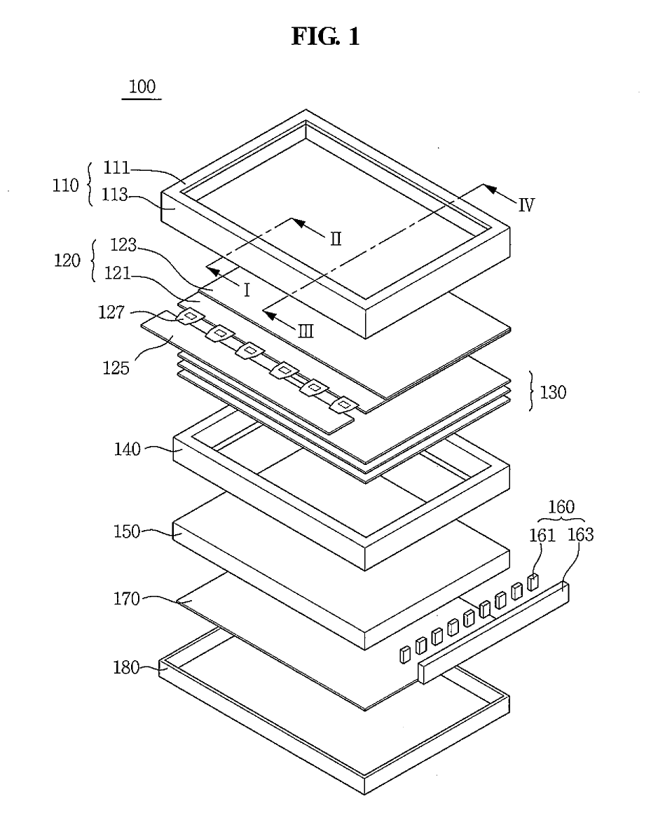

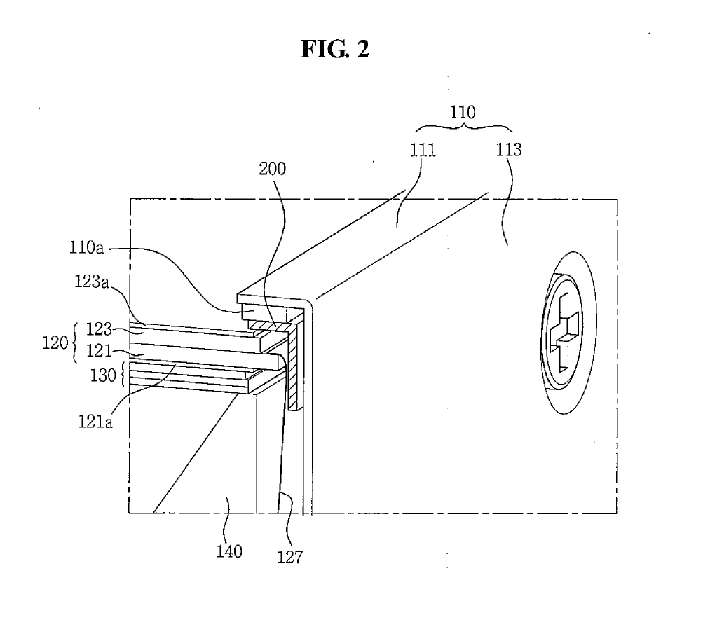

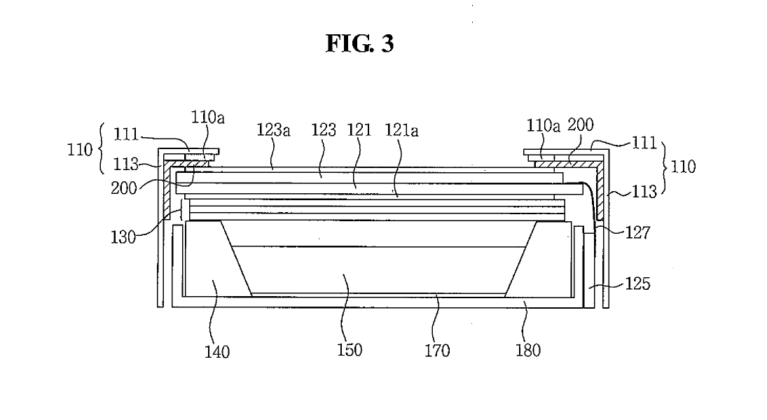

FIG. 1 is an exploded perspective view illustrating a display device according to an embodiment of the present invention, FIG. 2 is an inner perspective view taken along the line I-II of FIG. 1, and FIG. 3 is a cross-sectional view taken along the line III-IV of FIG. 1.

Referring to FIGS. 1 to 3, a display device 100 according to an embodiment of the present invention may include an upper frame (or a top chassis) 110, a display panel 120, an optical sheet 130, a middle frame (or a mold frame) 140, a light guide plate 150, a light source unit 160, a reflective sheet 170, and a lower frame (or a bottom chassis) 180.

Hereinafter, a backlight unit is to be understood as including the optical sheet 130, the middle frame 140, the light guide plate 150, the light source unit 160, the reflective sheet 170, and the lower frame 180.

The upper frame 110 has an opening for exposing an active area of the display panel 120 to the outside and may be disposed to cover an edge portion of an upper surface and side surfaces of the display panel 120.

The upper frame 110 may include a bezel portion 111 (e.g., a bezel unit) configured to cover the edge portion of the upper surface of the display panel 120 and a sidewall portion 113 bent downwards from the bezel portion 111 and configured to cover the side surfaces of the display panel 120.

The bezel portion 111 is configured to fix the edge portion of the upper surface of the display panel 120 and to prevent the display panel 120 from being separated from the backlight unit. The sidewall portion 113 may be fixed to the middle frame 140 and the lower frame 180. The sidewall portion 113 may be fixed to the middle frame 140 and the lower frame 180 by hooks and/or screws.

The upper frame 110 may be formed of a rigid metal material, such as stainless steel, or a material having good heat dissipation properties, such as aluminum or an aluminum alloy.

Referring to FIGS. 2 and 3, the display device 100 may include a pad 110a disposed between the upper frame 110 and the display panel 120. For example, the pad 110a may be disposed between the bezel portion 111 of the upper frame 110 and the display panel 120.

The pad 110a may be fixed to an inner surface of the bezel portion 111 of the upper frame 110 using an adhesive member, such as a double-sided tape.

The pad 110a may have a quadrangular shape (e.g., a quadrangular strap form) extending along the bezel portion 111 or may be two or more separate pieces (e.g., separate straps). In an embodiment in which the pad 110a is two or more separate pieces, the respective pads 110a may be disposed along facing sides (e.g., opposite sides) of the bezel portion 111.

The pad 110a may be formed of a black-colored (e.g., black-based) material having elastic properties, such as rubber. The pad 110a is configured to prevent (or protect from) damage to the display panel 120 caused by the upper frame 110 that is formed of a metal material, to release electrostatic charges stored in the display panel 120 to the outside, and to prevent light leakage between the upper frame 110 and the display panel 120.

The display device 100 may further include a film member 200 disposed between the pad 110a and the display panel 120. The film member 200 is bent toward the sidewall portion 113 and disposed between the sidewall portion 113 of the upper frame 110 and the side surfaces of the display panel 120.

The film member 200 may be fixed to an inner surface of the sidewall portion 113 of the upper frame 110 using an adhesive member.

The film member 200 may include a polytetrafluoroethylene (PTFE)-based film, a flame-retarding polyvinyl chloride (PVC) film, a flame-retarding polyester film, a flame-retarding polyether film, a polyethyleneimine (PEI) film, a silicon film, a silicon rubber film, a fluorine resin film, an insulating film, a teflon film, a polyvinyl chloride (PVC)-based protective film, a polyethylene (PE)-based film, and/or a polyolefin (PO)-based film.

A coefficient of static friction between the pad 110a and the film member 200 may be greater than a coefficient of static friction between the film member 200 and the display panel 120.

In some embodiments, the display panel 120 may include polarizers 121a and 123a (e.g., a lower polarizer 121a and an upper polarizer 123a) and at least one substrate 121 and/or 123. The polarizers 121a and 123a being on the at least one substrate 121 and/or 123. In one embodiment, the coefficient of static friction between the pad 110a and the film member 200 may be greater than the coefficient of static friction between the film member 200 and the polarizers 121a and 123a.

Therefore, although the display panel 120 moves from side to side, the pad 110a may not be separated from the upper frame 110.

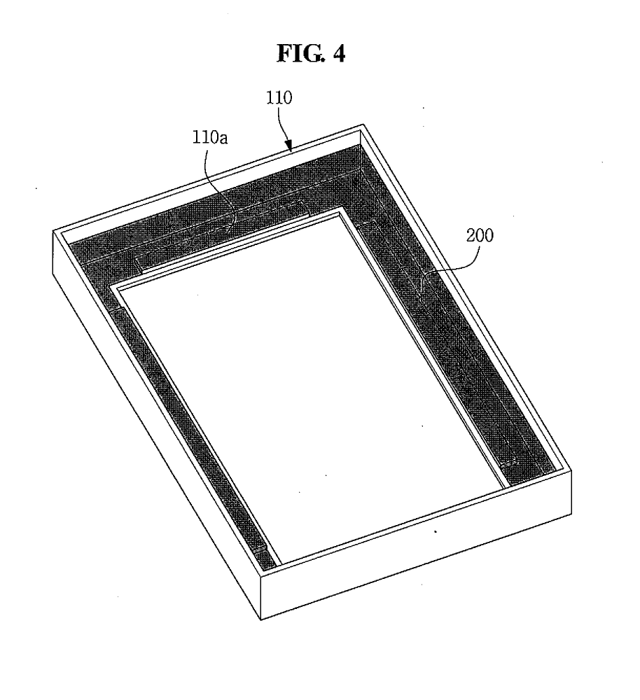

FIGS. 4 to 6 are rear views showing an upper frame to illustrate an arrangement of a film member according to embodiments of the present invention.

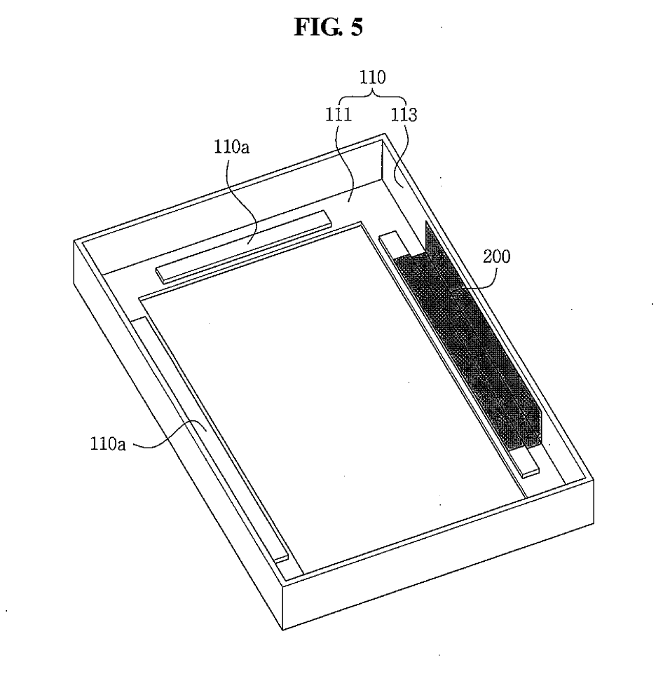

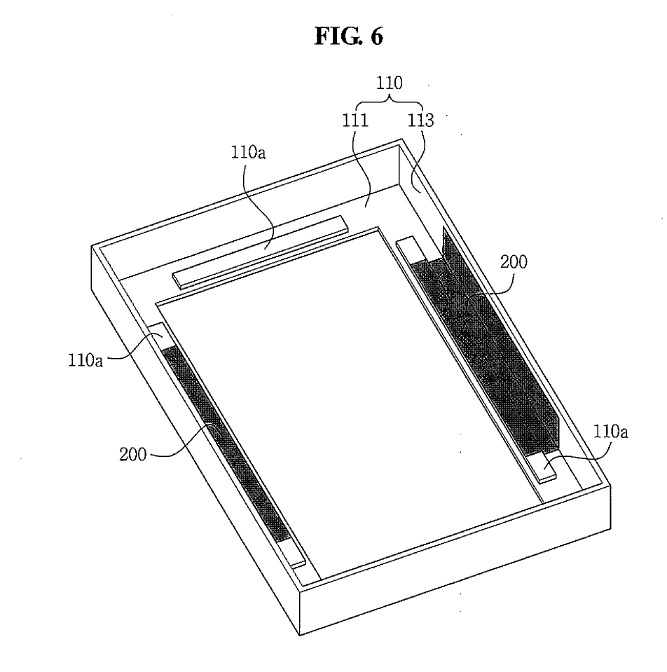

Referring to FIGS. 4 to 6, the film member 200 may have a quadrangular shape (e.g., a quadrangular strap form) extending along the upper frame 110 (refer to FIG. 4), may have a quadrangular shape (e.g., a strap form) extending along the upper frame 110 (refer to FIG. 5), or may be two or more separate pieces (e.g., separate straps) (refer to FIG. 6).

In an embodiment in which the film member 200 is two or more separate pieces, the respective film members 200 may be disposed along facing sides (e.g., opposite sides) of the upper frame 110. In this embodiment, the respective film members 200 may be disposed to face each other.

The film member 200 may have dust- and moisture-resistant properties in order to prevent infiltration of moisture and undesired materials into the display device and may have an opaque, black-based color so as to prevent (or protect from) light leakage between the upper frame 110 and the display panel 120.

The film member 200 may have a smaller thickness compared to a gap between the sidewall portion 113 of the upper frame 110 and the side surface of the display panel 120. The film member 200 may prevent (or protect from) damage to the side surfaces of the display panel 120 caused by the sidewall portion 113 of the upper frame 110.

Referring to FIGS. 1 to 3, the display panel 120 may be provided in a quadrilateral panel form to display images using light. The display panel 120 includes a first substrate 121, a second substrate 123 disposed to face the first substrate 121, and a liquid crystal layer disposed between the first substrate 121 and the second substrate 123.

The first substrate 121 includes a plurality of pixel electrodes arranged in a matrix form, thin film transistors configured to apply a driving voltage to the respective pixel electrodes, and various signal lines configured to drive the pixel electrodes and the thin film transistors.

The second substrate 123 is disposed to face the first substrate 121 and includes a common electrode formed of a transparent conductive material and a color filter. The color filter has red, green, and blue color filters.

The liquid crystal layer is interposed between the first substrate 121 and the second substrate 123. The liquid crystal layer is configured to be rearranged according to an electric field formed between the pixel electrode and the common electrode. Accordingly, the liquid crystal layer varies or adjusts transmittance of light emitted from the backlight unit and the transmitted light passes through the color filter, such that an image can be displayed.

In addition, the lower polarizer 121a may be disposed on the rear surface of the first substrate 121, and the upper polarizer 123a may be disposed on the upper surface of the second substrate 123. The upper polarizer 123a and the lower polarizer 121a may have areas corresponding to the display panel 120. The upper polarizer 123a may only allow light having a certain (e.g., a predetermined) polarization direction among light incident from the outside to pass therethrough and may absorb or block the other light. The lower polarizer 121a may only allow light having a certain (e.g., a predetermined) polarization direction among light emitted from the backlight unit to pass therethrough and may absorb or block the other light

A driving circuit substrate 125 may be disposed at (e.g., on) at least one side of the display panel 120. The driving circuit substrate 125 may apply driving signals to the various signal lines disposed on the first substrate 121. The driving circuit substrate 125 includes a gate driving circuit (e.g., a gate driving circuit substrate) configured to apply scan signals and a data driving circuit (e.g., a data driving circuit) substrate configured to apply data signals. In FIG. 1, the driving circuit substrate 125 is disposed at only one side of the display panel 120; however, embodiments of the present invention are not limited thereto.

The display panel 120 and the driving circuit substrate 125 are electrically connected to each other by at least one flexible printed circuit board 127. One end portion of the flexible printed circuit board 127 overlaps a part of the first substrate 121 and is electrically connected to the first substrate 121. The other end portion of the flexible printed circuit board 127 overlaps a part of the driving circuit substrate 125 and is electrically connected to the driving circuit substrate 125. The flexible printed circuit board 127 may be, for example, a chip on film (COF) or a tape carrier package (TCP). Hereinafter, it is assumed that the COF is used as the flexible printed circuit board 127. FIG. 1 illustrates that six flexible printed circuit boards 127 are disposed in the display device 100. However, embodiments of the present invention are not limited thereto, and thus, the number of the flexible printed circuit boards 127 may be varied or adjusted depending on the size and the driving methods of the display panels.

A driving chip may be mounted on the flexible printed circuit board 127. The driving chip may generate various driving signals for driving the display panel 120. The driving chip is formed by integrating a timing controller and a data driving circuit in a single chip. The driving chip may be expressed as a driver integrated circuit (IC) or a source integrated circuit (IC).

The plurality of flexible printed circuit boards 127 attached at one side of the display panel 120 are bent along the sidewall portion 113 of the upper frame 110 and a side wall of the lower frame 180, and the driving circuit substrate 125 may be disposed on the side wall of or on an edge portion of a rear surface of the lower frame 180.

The optical sheet 130 is disposed on the light guide plate 150 and is configured to diffuse and/or collect light transmitted from the light guide plate 150. The optical sheet 130 includes a diffusion sheet, a prism sheet, and a protective sheet. In FIG. 1, it is illustrated that three optical sheets 130 are provided; however, two, four, or more optical sheets may be provided.

The diffusion sheet is configured to disperse light incident from the light guide plate 150 so as to prevent (or protect) the light from being locally or partly concentrated.

The prism sheet may include prisms having a triangular cross-section and aligned in an arrangement (e.g., a predetermined arrangement) on one surface thereof. The prism sheet is disposed on the diffusion sheet and may collect light diffused from the diffusion sheet in a direction perpendicular (or normal) to the display panel 120.

The protective sheet may be formed on the prism sheet and may protect a surface of the prism sheet and diffuse light to achieve a uniform light distribution.

The middle frame 140 has a quadrilateral-loop form. The middle frame 140 accommodates and supports the display panel 120, the optical sheet 130, the light guide plate 150, and the like. The middle frame 140 may be formed as a single unit, as illustrated in FIG. 1. However, a plurality of units may be assembled to form the middle frame 140.

The light guide plate 150 is configured to uniformly supply light generated by (e.g., supplied from) the light source unit 160 to the display panel 120. The light guide plate 150 is disposed adjacent to the light source unit 160 and is accommodated in the lower frame 180. The light guide plate 150 may be formed having a quadrilateral panel shape or form but is not limited thereto. Thus, in an embodiment in which an LED chip is used as the light source, the light guide plate 150 may have various forms including a groove and/or a protrusion (e.g., a predetermined groove and/or protrusion) according to a position of the light source.

The light guide plate 150 is described as a plate for ease of description, but it may be a sheet or a film to reduce the thickness of display devices. That is, the light guide plate 150 is to be understood as having a concept that includes not only a plate but also a film for guiding light.

The light guide plate 150 may be formed of a light-transmissive material including, for example, acrylic resins, such as polymethylmethacrylate (PMMA) or polycarbonate (PC), so as to guide light efficiently.

The reflective sheet 170 may be disposed between the light guide plate 150 and the lower frame 180. The reflective sheet 170 reflects light emitted downwards (e.g., away from the display panel 120) from the light guide plate 150 to the display panel 120, thereby enhancing light efficiency.

The reflective sheet 170 may be formed of, for example, polyethylene terephthalate (PET) so as to have reflective properties. Further, one surface of the reflective sheet may be coated with a diffusion layer including, for example, titanium dioxide. Further, the reflective sheet 170 may be formed of a material including metal, such as silver (Ag).

The light source unit 160 includes one or more light sources 161 and a circuit substrate 163 on which the light sources 161 are disposed.

The light sources 161 may be disposed at an edge portion or on a light incident surface of the light guide plate 150. For example, the light sources 161 may emit light toward the edge portion or the light incident surface of the light guide plate 150. Each light source 161 may include at least one LED chip and a package accommodating the LED chip. For example, the LED chip may be a gallium nitride (GaN)-based LED chip that emits blue light.

The number of the light sources 161 may vary in consideration of the size, luminance uniformity, and the like of the display panel 120. The circuit substrate 163 may be a printed circuit board (PCB) or a metal PCB.

A wavelength conversion unit may be disposed between the light guide plate 150 and the light source unit 160. The wavelength conversion unit may include a substance that is configured to change a wavelength of light. For example, the wavelength conversion unit may change a wavelength of blue light emitted from a blue LED light source such that the blue light is converted to white light.

Further, a heat dissipating member may be disposed between the light source unit 160 and the lower frame 180. The heat dissipating member may release heat generated from the light source unit 160 to outside the display device 100. In an embodiment in which the light source unit 160 is disposed on one side surface of the lower frame 180 in a bar or line shape or form, a metal frame having a bar or line shape or form may be disposed as the heat dissipating member. Accordingly, the heat dissipating member may have various suitable forms according to the shape or form of the light source unit 160.

The lower frame 180 may be formed of a rigid metal material, such as stainless steel, or a material having good heat dissipating properties, such as aluminum or aluminum alloys. The lower frame 180 is configured to provide a framework of the display device and to protect a variety of components accommodated therein.

From the foregoing, it will be appreciated that various embodiments in accordance with the present disclosure have been described herein for purposes of illustration and that various modifications may be made without departing from the scope and spirit of the present teachings. Accordingly, the various embodiments disclosed herein are not intended to be limiting of the true scope and spirit of the present teachings.

What is claimed is:

1. A display device comprising:
a display panel;
an upper frame configured to cover an edge portion of an upper surface and side surfaces of the display panel;
a pad between the display panel and the upper frame; and
a film member between the pad and the display panel.

2. The display device of claim 1, wherein a coefficient of static friction between the pad and the film member is greater than a coefficient of static friction between the film member and the display panel.

3. The display device of claim 1, wherein the upper frame comprises a bezel portion covering the edge portion of the upper surface of the display panel and a sidewall portion bent from the bezel portion and covering the side surfaces of the display panel.

4. The display device of claim 3, wherein the pad is between the bezel portion of the upper frame and the display panel.

5. The display device of claim 4, wherein the film member is bent toward the sidewall portion of the upper frame and is between the sidewall portion of the upper frame and the side surfaces of the display panel.

6. The display device of claim 5, wherein the film member is attached to the sidewall portion of the upper frame.

7. The display device of claim 3, wherein a thickness of the film member is smaller than a gap between the sidewall portion of the upper frame and the display panel.

8. The display device of claim 1, wherein the display panel comprises a substrate and a polarizer on the substrate, and
wherein the film member is between the pad and the polarizer.

9. The display device of claim 8, wherein a coefficient of static friction between the pad and the film member is greater than a coefficient of static friction between the film member and the polarizer.

10. The display device of claim 1, wherein the film member has a quadrangular shape extending along the upper frame.

11. The display device of claim 1, wherein the film member has a strap shape extending along the upper frame.

12. The display device of claim 11, wherein the film member comprises two or more separate pieces.

13. The display device of claim 12, wherein the two or more pieces of the film member are at opposite sides of the upper frame.

14. The display device of claim 1, wherein the film member comprises a polytetrafluoroethylene-based film, a flame-retarding polyvinyl chloride film, a flame-retarding polyester film, a flame-retarding polyether film, a polyethyleneimine film, a silicon film, a silicon rubber film, a fluorine resin film, an insulating film, a teflon film, a polyvinyl chloride-based protective film, a polyethylene-based film, and/or a polyolefin-based film.

15. The display device of claim 1, wherein the film member is opaque.
